(19) United States
(12) Patent Application Publication
(10) Pub. No.: US 2025/0389753 A1
(43) Pub. Date: Dec. 25, 2025

(54) ELECTRICALLY CONDUCTIVE CONTACT PIN

(71) Applicant: POINT ENGINEERING CO., LTD., Asan-si (KR)

(72) Inventors: Bum Mo AHN, Suwon-si (KR); Seung-Ho PARK, Hwaseong-si (KR); Chang Hee HONG, Yongin-Si (KR)

(21) Appl. No.: 18/839,870

(22) PCT Filed: Feb. 22, 2023
(86) PCT No.: PCT/KR2023/002557

§ 371 Date: Mar. 4, 2025

(30) Foreign Application Priority Data
Feb. 25, 2022 (KR) 10-2022-0025347

(51) Int. Cl. G01R 1/067; G01R 1/04; G01R 1/073

(52) U.S. Cl. CPC G01R 1/06722; G01R 1/0466; G01R 1/06733; G01R 1/07342

(57) ABSTRACT

The invention provides an electrically conductive contact pin that improves test reliability for a test object and prevents separation in a side opening direction of a guide hole due to a lower catch portion.

### TECHNICAL FIELD

The present disclosure relates to present disclosure relates to an electrically conductive contact pin.

### BACKGROUND ART

A test for electrical characteristics of a semiconductor device is performed by approaching a test object (semiconductor wafer or semiconductor package) to a test device having a plurality of electrically conductive contact pins and then bringing the respective electrically conductive contact pins into contact corresponding external terminals (solder balls or bumps) on the test object. Examples of test devices include, but are not limited to, probe cards or test sockets.

Conventional test sockets include a pogo-type socket and a rubber-type socket.

An electrically conductive contact pin (hereinafter referred to as a “pogo-type socket pin”) used in the pogo-type test socket includes a pin portion and a barrel accommodating the pin portion. The pin portion is provided with a spring member between plungers at opposite ends of the pin portion to enable application of required contact pressure and shock absorption at a contact position. In order for the pin portion to slide within the barrel, a gap has to exist between an outer surface of the pin portion and an inner surface of the barrel. However, since the pogo-type socket pin is used by separately manufacturing the barrel and the pin portion and then assembling them together, the gap between the outer surface of the pin portion and the inner surface of the barrel is increased more than necessary, so it is impossible to precisely manage the gap. Therefore, electrical signals are lost and distorted in the process of being transferred to the barrel via the opposite plungers, causing a problem in that contact stability is not constant. In addition, the pin portion has a pointed tip portion to increase the contact effect with an external terminal of a test object. The pointed tip portion generates a mark or a groove due to press-contact on the external terminal of the test object after testing. The loss of the contact shape of the external terminal causes an error in vision inspection and lowers the reliability of the external terminal in a subsequent process such as soldering.

Meanwhile, an electrically conductive contact pin (hereinafter referred to as a “rubber-type socket pin”) used in the rubber-type test socket has a structure in which conductive microballs are disposed inside a silicon rubber made of a rubber material. When stress is applied by placing a test object (e.g., a semiconductor package) and closing the socket, conductive microballs made of gold strongly press each other and increase conductivity, making microballs electrically connected. However, the rubber-type socket pin has a problem in that contact stability is secured only when the socket pin is pressed with an excessive pressing force.

Meanwhile, with the advancement and high integration of semiconductor technology, the pitch of the external terminals of the test object has become narrower. In the case of the rubber-type socket pin, the socket pin is produced by preparing a molding material in which conductive particles are distributed in a fluid elastic material, inserting the molding material into a predetermined mold, and applying a magnetic field in the thickness direction to arrange the conductive particles in the thickness direction. Due to this manufacturing technique, when the distance between magnetic fields is narrowed, the conductive particles are irregularly oriented and a signal flows in the plane direction. Thus, the conventional rubber-type socket pin has limitations in responding to the trend toward narrow pitch technology.

In addition, since the pogo-type socket pin is used by separately manufacturing the barrel and the pin portion and then assembling them together, it is difficult to manufacture the socket pin in a small size. Thus, the pogo-type socket pin also has limitations in responding to the trend toward narrow pitch technology.

Accordingly, there is a need to develop a new type of electrically conductive contact pin and a test device having the same that can improve the test reliability for a test object to enable compliance with the recent technology trend.

### DOCUMENTS OF RELATED ART

### Patent Documents

(Patent Document 1) Korean Patent No. 10-0659944
(Patent Document 2) Korean Patent No. 10-0952712

### DISCLOSURE

### Technical Problem

Accordingly, the present disclosure has been made keeping in mind the above problems occurring in the related art, and an objective of the present disclosure is to provide an electrically conductive contact pin that improves test reliability for a test object.

Another objective of the present disclosure is to prevent an electrically conductive contact pin from being separated in the direction of a first side opening of a guide hole due to a lower catch portion.

### Technical Solution

In order to accomplish the above objectives, the present disclosure provides an electrically conductive contact pin having a lower catch portion. The lower catch portion may be compressed and deformed inward in a width direction, inserted into a first side opening of a guide hole of a guide plate, and restored while passing through a second side opening of the guide hole and brought into contact with a lower surface of the guide plate so that the electrically conductive contact pin is prevented from being separated in a direction of the first side opening.

In addition, the electrically conductive contact pin may include: a first connection portion; a second connection portion; a support portion extending in a length direction; and an elastic portion connected to at least one of the first connection portion and the second connection portion and elastically deformable along the length direction. The lower catch portion may be connected to the support portion.

In addition, the electrically conductive contact pin may include: a first connection portion; a second connection portion; a support portion extending in a length direction; and an elastic portion connected to at least one of the first connection portion and the second connection portion and elastically deformable along the length direction. The lower catch portion may be connected to the second connection portion.

In addition, the lower catch portion may include an inclined portion inclined inward in the width direction.

In addition, the lower catch portion may further include a shoulder portion extending linearly from an end of the inclined portion. When the lower catch portion is restored while passing through the second side opening of the guide hole, an upper surface of the shoulder portion may be brought into contact with the lower surface of the guide plate to prevent the electrically conductive contact pin from being separated in the direction of the first side opening.

In addition, the lower catch portion may further include a shoulder portion protruding inward in the width direction from an end of the inclined portion. When the lower catch portion is restored while passing through the second side opening of the guide hole, an upper surface of the shoulder portion may be brought into contact with the lower surface of the guide plate to prevent the electrically conductive contact pin from being separated in the direction of the first side opening.

In addition, the upper surface of the shoulder portion may be formed as a flat surface.

In addition, the electrically conductive contact pin may further include: an auxiliary shoulder portion protruding outward in the width direction on at least a part of the support portion in the length direction. When the lower catch portion is restored while passing through the second side opening of the guide hole, an upper surface of the auxiliary shoulder portion may be brought into contact with the lower surface of the guide plate to prevent the electrically conductive contact pin from being separated in the direction of the first side opening.

In addition, the electrically conductive contact pin may further include: an upper catch portion corresponding vertically to the lower catch portion in the length direction. The upper catch portion may be connected to the support portion and may be formed to protrude outward from the support portion in the width direction.

In addition, the first connection portion may include: a contact portion; and an upward protrusion.

In addition, the first connection portion may include: a contact portion; a contact cavity formed in the contact portion; and a contact protrusion extending in the length direction from an upper surface of the contact portion.

In addition, the second connection portion may include:

a connection body; a connection cavity formed in the connection body; and at least one pad connection protrusion provided on a lower surface of the connection body.

In addition, the electrically conductive contact pin may further include: a flange portion connected to at least one of the first connection portion and the elastic portion and provided between the support portion and the elastic portion.

In addition, the flange portion may extend in the length direction from a lower surface of the first connection portion and may be provided between the support portion and the elastic portion.

In addition, the electrically conductive contact pin may further include: a stopper portion connected to at least one of the support portion and the elastic portion and extending in the width direction.

In addition, the electrically conductive contact pin may further include: a stopper portion formed by a portion recessed inward in the width direction on at least a part of the support portion.

In addition, the electrically conductive contact pin may be formed by stacking a plurality of metal layers in a thickness direction of the electrically conductive contact pin.

In addition, the electrically conductive contact pin may include: a plurality of fine trenches provided on a side surface thereof.

### Advantageous Effects

The present disclosure can provide an electrically conductive contact pin that improve test reliability for a test object.

In addition, the present disclosure can provide an electrically conductive contact pin that is prevented from being separated in the direction of a first side opening of a guide hole due to a lower catch portion.

In addition, the present disclosure can provide an electrically conductive contact pin that is longitudinally buffered through the lower catch portion when excessive compressive strain is applied.

### DESCRIPTION OF DRAWINGS

FIG. 1 is a plan view illustrating an electrically conductive contact pin according to a preferred embodiment of the present disclosure.

FIG. 2 is a perspective view illustrating the electrically conductive contact pin according to the first preferred embodiment of the present disclosure.

FIG. 3 is a perspective view illustrating an installation member according to a preferred embodiment of the present disclosure.

FIG. 4 is a view illustrating electrically conductive contact pins according to the first preferred embodiment of the present disclosure are installed in the installation member.

FIG. 5 is a view illustrating a test object is tested using a test device according to a preferred embodiment of the present disclosure.

FIG. 6 is a view illustrating current paths of the electrically conductive contact pin according to the first preferred embodiment of the present disclosure.

FIGS. 7a to 7d are views illustrating a method of manufacturing the electrically conductive contact pin according to the first preferred embodiment of the present disclosure, in which FIG. 7a is a plan view illustrating a mold in which an inner space is formed, FIG. 7b is a sectional view taken along line A-A′ of FIG. 7a, FIG. 7c is a plan view illustrating an electroplating process is performed on the inner space, and FIG. 7d is sectional view taken along line A-A′ of FIG. 7c.

FIG. 8 is an enlarged view illustrating a part of a side surface of the electrically conductive contact pin according to the first preferred embodiment of the present disclosure.

FIG. 9 is a view illustrating an electrically conductive contact pin according to a second preferred embodiment of the present disclosure is installed in an installation member.

FIG. 10 is a view illustrating an electrically conductive contact pins according to a third preferred embodiment of the present disclosure is installed in an installation member.

### MODE FOR INVENTION

Contents of the description below merely exemplify the principle of the present disclosure. Therefore, those of ordinary skill in the art may implement the theory of the present disclosure and invent various apparatuses which are included within the concept and the scope of the present disclosure even though it is not clearly explained or illustrated in the description. Further, all conditional terms and embodiments listed in this description are, in principle, intended to implement the theory of the present disclosure and invent various apparatuses which are included within the concept and the scope of the present disclosure. Furthermore, all conditional terms and embodiments listed in this description are, in principle, clearly intended for the purpose of understanding the concept of the present disclosure, and one should understand that the present disclosure is not limited to the exemplary embodiments and the conditions.

The above described objectives, features, and advantages will be more apparent through the following detailed description related to the accompanying drawings, and thus those of ordinary skill in the art may easily implement the technical spirit of the present disclosure.

The embodiments of the present disclosure are described with reference to sectional views and/or perspective views which schematically illustrate ideal embodiments of the present disclosure. For explicit and convenient description of the technical content, sizes or thicknesses of films and regions in the figures may be exaggerated. As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. The technical terms used herein are for the purpose of describing particular embodiments only and should not be construed as limiting the present disclosure. As used herein, the singular forms are intended to include the plural forms as well, unless the context clearly indicates otherwise. It will be further understood that the terms “comprise” or “include” when used herein, specify the presence of stated features, integers, steps, operations, elements, components, and/or combinations thereof but do not preclude the presence or addition of one or more other features, integers, steps, operations, elements, components, and/or combinations thereof.

Hereinafter, preferred embodiments of the present disclosure will be described in detail with reference to the accompanying drawings. Wherever possible, the same reference numerals will be used throughout different embodiments and the description to refer to the same or like elements or parts. In addition, the configuration and operation already described in other embodiments will be omitted for convenience.

An electrically conductive contact pin 100a, 100b, 100c according to a preferred embodiment of the present disclosure is provided in a test device 10 and is used to transmit electrical signals by making electrical and physical contact with a test object 400. The test device 10 may be a test device used in a semiconductor manufacturing process, for example, a probe card or a test socket.

The test device 10 includes the electrically conductive contact pin 100a, 100b, 100c and an installation member 200 having a through-hole 210 for receiving the electrically conductive contact pin 100a, 100b, 100c. The installation member 200 may be, for example, a guide plate GP having a guide hole GH.

The electrically conductive contact pin 100a, 100b, 100c may be a probe pin provided in the probe card or a socket pin provided in the test socket. In the following, the socket pin will be exemplified and described as an example of the electrically conductive contact pin 100a, 100b, 100c. However, the electrically conductive contact pin 100a according to the preferred embodiment of the present disclosure is not limited thereto and includes any pin for checking whether the test object 400 is defective by applying electricity.

Hereinafter, first to third embodiments will be separately described, but embodiments in which the elements of each embodiment are combined are also included in exemplary embodiments of the present disclosure.

In the following description, the width direction of the electrically conductive contact pin 100a, 100b, 100c refers to the +x direction indicated in the drawings, the length direction of the electrically conductive contact pin 100a, 100b, 100c refers to the ty direction indicated in the drawings, and the thickness direction of the electrically conductive contact pin 100a, 100b, 100c refers to the ±z direction indicated in the drawings.

The electrically conductive contact pin 100a, 100b, 100c has an overall length L in the length direction, an overall thickness H in the thickness direction (+Z direction) orthogonal to the length direction (ty direction), and an overall width W in the width direction (+x direction) orthogonal to the length direction (ty direction).

### First Embodiment

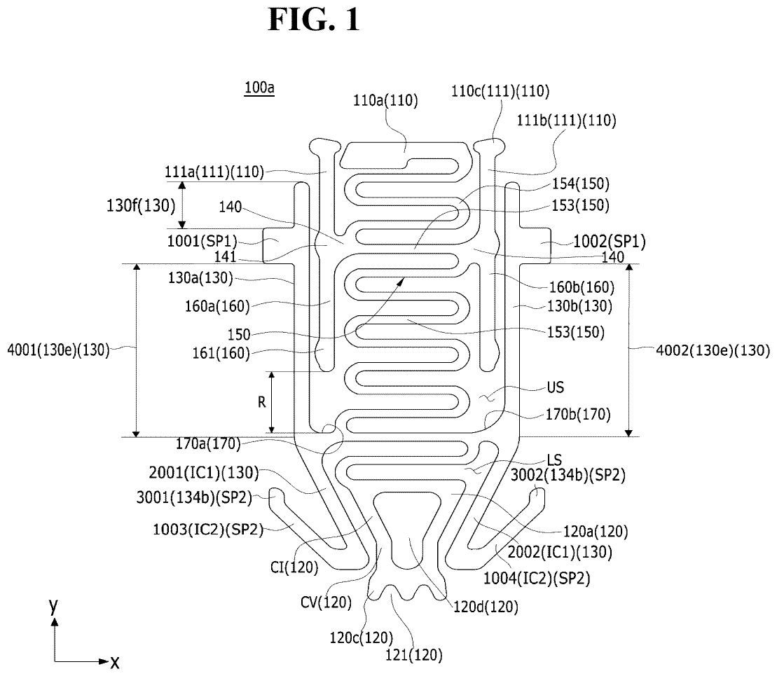

Hereinafter, an electrically conductive contact pin according to a first preferred embodiment of the present disclosure (hereinafter referred to as “electrically conductive contact pin 100a according to the first embodiment”) will be described with reference to FIGS. 1 to 8.

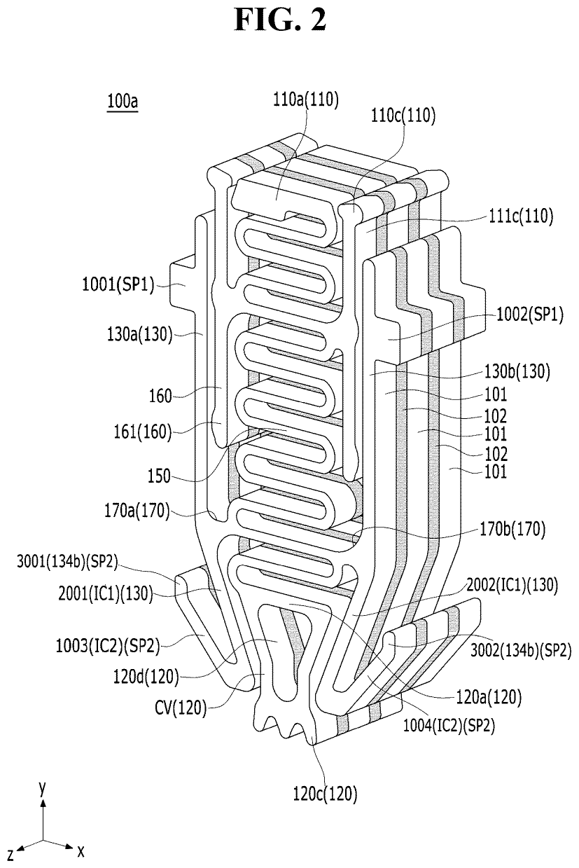

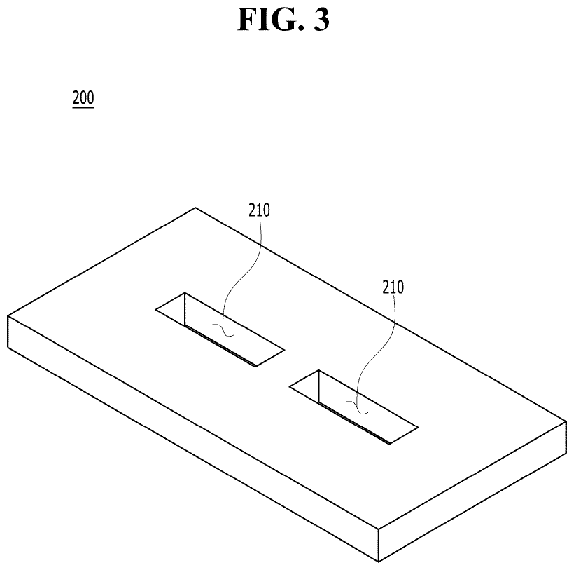

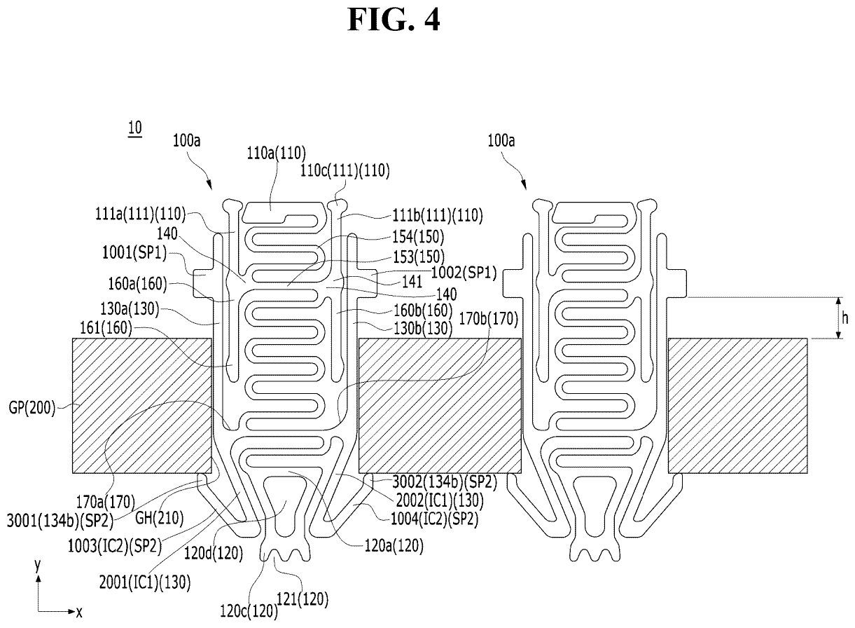

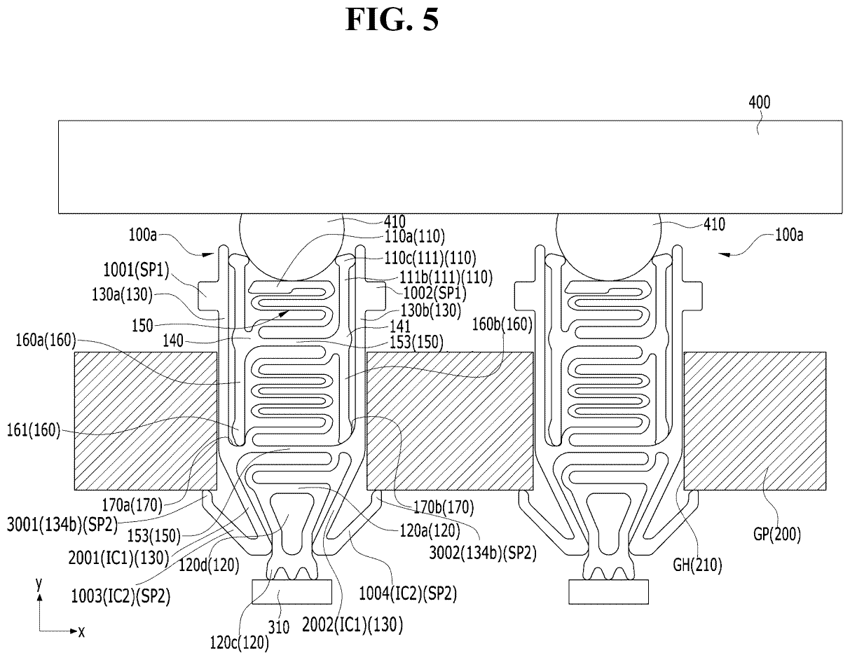

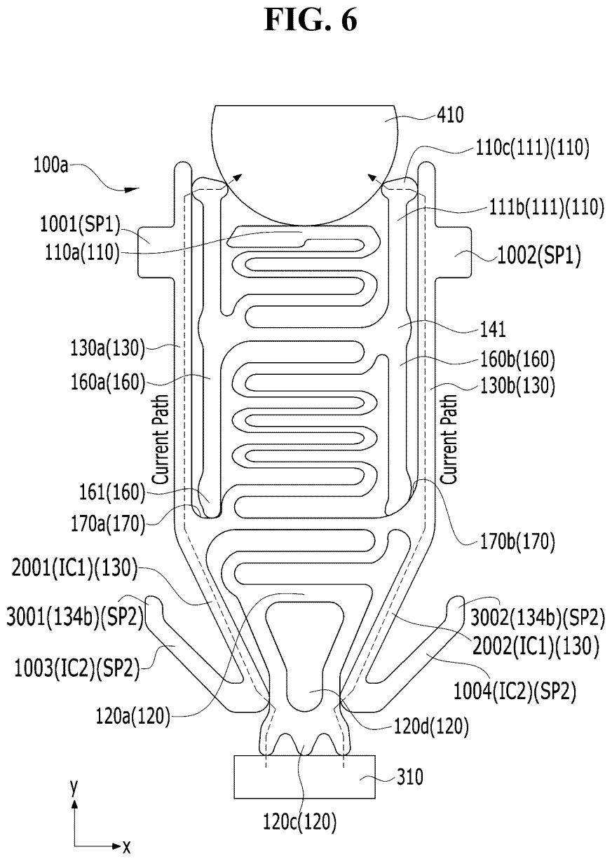

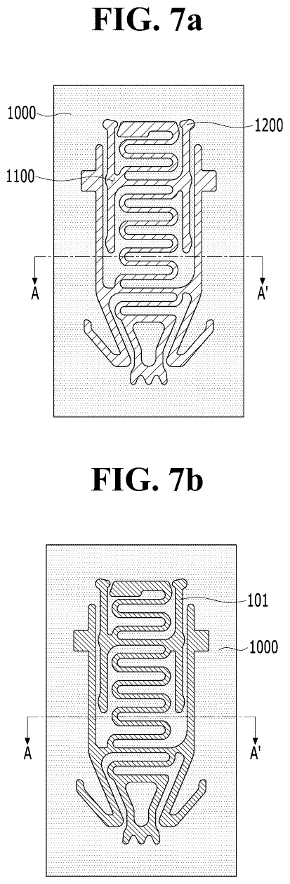

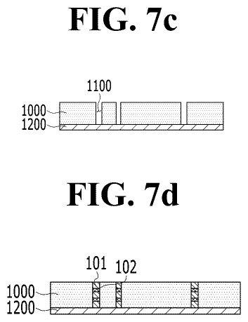

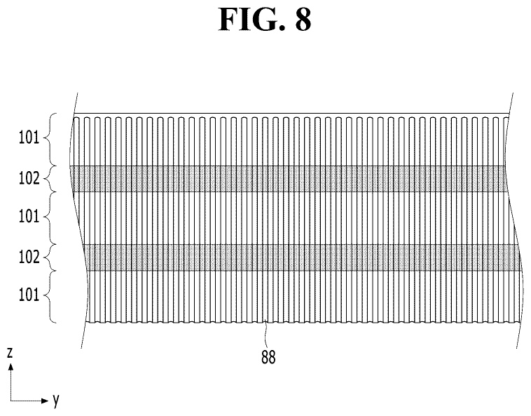

FIG. 1 is a plan view illustrating the electrically conductive contact pin 100a according to the first embodiment. FIG. 2 is a perspective view illustrating the electrically conductive contact pin 100a according to the first embodiment. FIG. 3 is a perspective view illustrating an installation member 200 according to a preferred embodiment of the present disclosure. FIG. 4 is a view illustrating electrically conductive contact pins 100a according to the first embodiment are installed in the installation member 200. FIG. 5 is a view illustrating a test object 400 is tested using a test device 10 according to a preferred embodiment of the present disclosure. FIG. 6 is a view illustrating current paths of the electrically conductive contact pin 100a according to the first embodiment. FIGS. 7a to 7d are views illustrating a method of manufacturing the electrically conductive contact pin 100a according to the first embodiment, in which FIG. 7a is a plan view illustrating a mold 1000 in which an inner space 1100 is formed, FIG. 7b is a sectional view taken along line A-A′ of FIG. 7a, FIG. 7c is a plan view illustrating an electroplating process is performed on the inner space 1100, and FIG. 7d is sectional view taken along line A-A′ of FIG. 7c. FIG. 8 is an enlarged view illustrating a part of a side surface of the electrically conductive contact pin 100a according to the first embodiment.

Referring to FIGS. 1 and 2, the electrically conductive contact pin 100a according to the first embodiment includes a first connection portion 110, a second connection portion 120, a support portion 130 extending in the length direction (+y direction), an elastic portion 150 connected to at least one of the first connection portion 110 and the second connection portion 120 and elastically deformable along the length direction (ty direction), a lower catch portion SP2 connected to the support portion 130, an upper catch portion SP1 vertically corresponding to the lower catch portion SP2 in the length direction (ty direction), a flange portion 160 provided between the support portion 130 and the elastic and extending in the length direction (ty portion 150 direction), and a stopper portion 170 connected to at least one of the support portion 130 and the elastic portion 150 and extending in the width direction.

The first connection portion 110, the second connection portion 120, the support portion 130, the elastic portion 150, the lower catch portion SP2, the upper catch portion SP1, and the stopper portion 170 are manufactured simultaneously through a plating process. The electrically conductive contact pin 100a according to the first embodiment is formed using the mold 1000 having the inner space 1100 by filling the inner space 1100 with a metal material through electroplating. Therefore, the first connection portion 110, the second connection portion 120, the support portion 130, the elastic portion 150, the lower catch portion SP2, the upper catch portion SP1, and the stopper portion 170 are integrally manufactured to form a single body. A conventional electrically conductive contact pin is provided by separately manufacturing a barrel and a pin portion and then assembling them. However, the electrically conductive contact pin 100a according to the first embodiment has a structural difference in that it is provided as a single body by simultaneously manufacturing the first connection portion 110, the second connection portion 120, the support portion 130, the elastic portion 150, the lower catch portion SP2, the upper catch portion SP1, and the stopper portion 170 through the plating process.

The electrically conductive contact pin 100a according to the first embodiment has a uniform cross-sectional shape in the thickness direction (+z direction). In other words, the uniform cross-sectional shape on the x-y plane is formed by extending in the thickness direction (+z direction).

The electrically conductive contact pin 100a according to the first embodiment is formed by stacking a plurality of metal layers in the thickness direction (+z direction). The plurality of metal layers include a first metal layer 101 and a second metal layer 102.

The first metal layer 101 may be made of a metal having relatively high wear resistance compared to the second metal layer 102, preferably a metal selected from: the group consisting of rhodium (Rd), platinum (Pt), iridium (Ir), palladium (Pd), nickel (Ni), manganese (Mn), tungsten (W), phosphorus (Ph), and an alloy of these metals; the group consisting of a palladium-cobalt (PdCo) alloy and a palladium-nickel (PdNi) alloy; or the group consisting of a nickel-phosphor (NiPh) alloy, a nickel-manganese (NiMn) alloy, a nickel-cobalt (NiCo) alloy, and a nickel-tungsten (NiW) alloy. The second metal layer 102 may be made of a metal having relatively high electrical conductivity compared to the first metal layer 102, preferably a metal selected from the group consisting of copper (Cu), silver (Ag), gold (Au), and an alloy of these metals. However, the present disclosure is not limited thereto.

The first metal layer 101 is provided on each of a lower surface and an upper surface of the electrically conductive contact pin 100a in the thickness direction (+z direction), and the second metal layer 102 is provided between the respective first metal layers 101. For example, the electrically conductive contact pin 100a may be provided by sequentially stacking the first metal layer 101, the second metal layer 102, and the first metal layer 101 in the thickness direction (+z direction), and the number of stacked layers may be at least three.

The first connection portion 110 includes a contact portion 110a brought into contact with the test object 400 and an upward protrusion 111 having a contact protrusion 110c at an upper end thereof.

The contact portion 110a is a portion that is brought into contact with a connection terminal 410 of the test object 400. The contact portion 110a is formed to extend in the width direction (+x direction). A lower surface of an end of the contact portion 110a in the width direction (+x direction) is connected to the elastic portion 150.

The upward protrusion 111 is provided to extend upward from opposite sides of any one curved portion 154 of the elastic portion 150 including a plurality of straight portions 153 and a plurality of curved portions 154. The upward protrusion 111 extends in the length direction (+y direction) from the elastic portion (specifically, the curved portion 154) to a position corresponding to the first connection portion 110.

The upward protrusion 111 includes the contact protrusion 110c provided at a position corresponding to the first connection portion 110. The contact protrusion 110c is provided at the upper end of the upward protrusion 111 and protrudes outward in the width direction (+x direction). An upper surface of the contact protrusion 110c is formed to be inclined downward in the width direction (+x direction). Therefore, the upward protrusion 111 has an upper surface inclined downward in the width direction (+x direction).

The upward protrusion 111 may be brought into contact with the connection terminal 410 through the upper surface thereof and brought into contact with an upper end of the support portion 130 by a pressing force of the connection terminal 410 to form a current path.

Referring to FIG. 5, the first connection portion 110 is connected to the elastic portion 150 so that the first connection portion is elastically movable vertically (+y direction) by contact pressure. When testing the test object 400, the connection terminal 410 of the test object 400 is brought into contact with an upper surface of the first connection portion 110 and then brought into contact with the upper surface of the upward protrusion 111 while gradually compressing and deforming the elastic portion 150 connected to the first connection portion 110. The connection terminal 410 continues to move downward (−y direction) while compressing and deforming the elastic portion 150. As a result, the contact protrusion 110c of the upward protrusion 111 is brought into contact with the upper end of the support portion 130 to form a current path.

When an eccentric pressing force from the connection terminal 410 acts on the electrically conductive contact pin 100a according to the first embodiment, the upward protrusion 111 is brought into contact with the upper end of the support portion 130 through the contact protrusion 110c and supported by the upper end of the support portion 130. With this, the upward protrusion 111 prevents the electrically conductive contact pin 100a according to the first embodiment from being excessively buckled and deformed horizontally.

The elastic portion 150 has a uniform cross-sectional shape in the thickness direction n (+z direction) of the electrically conductive contact pin 100a according to the first embodiment. This is possible because the electrically conductive contact pin 100a according to the first embodiment is manufactured through the plating process.

The elastic portion 150 has a shape formed by repeatedly bending a plate having an actual width t in an “S” shape, and the actual width t of the plate is uniform throughout.

The elastic portion 150 is formed by alternately connecting the plurality of straight portions 153 and the plurality of curved portions 154. Each of the straight portions 153 connects the curved portions 154 adjacent in the left and right directions. Each of the curved portions 154 connects the straight portions 153 adjacent in the upper and lower directions. The curved portions 154 have an arc shape.

The straight portions 153 are disposed at a central portion of the elastic portion 150, and the curved portions 154 are disposed at outer peripheral portions of the elastic portion 150. The straight portions 153 are provided parallel to the width direction (±x direction) so that the curved portions 154 are more easily deformed by contact pressure.

The straight portions 153 are provided inside the support portions 130 and extend in the width direction (+x direction). At least one of the curved portions 154 functions as a connecting portion 140. The connecting portion 140 functions to connect the upward protrusion 111 and the flange portion 160 to each other.

The connecting portion 140 includes a thick portion 141. The thick portion 141 has a thickness larger than that of its surrounding portion in the width direction.

In the electrically conductive contact pin 100a according to the first embodiment, the thick portion 141 is formed to extend in width by a predetermined length in the width direction (+x direction) from opposite sides of the connecting portion 140. Therefore, the connecting portion 140 has the thick portion 141, and the upward protrusion 111 extends upward from the thick portion 141. The flange portion 160 extends downward from the thick portion 141. An outer surface of the thick portion 141 in the width direction (+x direction) has a convex shape and is formed to protrude by a predetermined length in the width direction (+x direction) beyond its surrounding portion. When the pressing force from the connection terminal 410 acts eccentrically on the elastic portion 150, any one upward protrusion 111 is brought into contact with the upper end of the support portion 130 and supported by the support portion 130, and any one flange portion 160 is brought into contact with a predetermined position on an inner surface of the support portion 130 and supported by the support portion 130. At this time, the thick portion 141 prevents a portion where the connecting portion 140 is connected to the upward protrusion 111 and the flange portion 160 from being easily damaged.

The flange portion 123 is located between the support portion 130 and the elastic portion 150 in the width direction (+x direction). When the elastic portion 150 is not compressed, the flange portion 160 and the support portion 130 are spaced apart from each other.

The flange portion 160 is connected to the elastic portion 150. The flange portion 160 is connected to any one of the curved portions 154 of the elastic portion 150 and extends downward. Therefore, the upward protrusion 111 extending upward and the flange portion 160 extending downward are provided with one curved portion 154 interposed therebetween.

The flange portion 160 has a predetermined length and extends downward from the connecting portion 140. Therefore, an end of the flange portion 160 is located at a position corresponding to an intermediate portion of the support portion 130 while extending by a predetermined length inside the support portion 130. The flange portion 160 is located inside the support portion 130 in the width direction (+x direction) to overlap at least a part of the support portion 130 (specifically, the upper end of the support portion 130 including the upper catch portion SP1) in the width direction (+x direction). Therefore, the flange portion 160 is brought into contact with the support portion 130 and supported by the support portion 130 due to the eccentric pressing force of the connection terminal 410.

In the electrically conductive contact pin 100a according to the first embodiment, an extended length of the flange portion 160 extending downward from the connecting portion 140 is equal to or larger than a predetermined length so that the end of the flange portion 160 is located at a position corresponding to the intermediate portion of the support portion 130. Therefore, the end of the flange portion 160 is located corresponding to the intermediate portion of the support portion 130 while being inserted by a predetermined length inside the support portion 130 in the length direction (ty direction). When the elastic portion 150 is eccentrically compressed by a predetermined amount due to the eccentric pressing force of the connection terminal 410 and accordingly the flange portion 160 is brought into contact with the support portion 130, the end of the flange portion 160 is brought into contact with the inner surface of the intermediate portion of the support portion 130. This prevents the elastic portion 150 from being excessively bucked.

The flange portion 160 has a first end connected to the elastic portion 150 and a second end serving as a free end. The flange portion 160 includes an auxiliary contact protrusion 161 provided at the free end thereof. The auxiliary contact protrusion 161 has an outer surface protruding convexly outward in the width direction (+x direction). The auxiliary contact protrusion 161 has a lower surface formed in a convex shape.

The flange portion 160 includes a first flange portion 160a located at a first side of the elastic portion 150 and a second flange portion 160b located at a second side of the elastic portion 150 oppositely to the first flange portion 160a. The first and second flange portions 160a and 160b extend downward from opposite sides of the elastic portion 150, respectively.

The support portions 130 are formed to extend in the length direction (+y direction) and are provided outside the first connection portion 110 in the width direction (±x direction). The support portion 130 includes a vertical extension portion 130f spaced parallel from the upward protrusion 111 while the elastic portion 150 is not compressively deformed, a vertical portion 130e spaced parallel from the flange portion 160, and an inclined extension portion IC1 inclinedly extending inward in the width direction (±x direction) from an end of the vertical portion 130e.

The support portion 130 is located to overlap at least a part of the upward protrusion 111 in the width direction (±x direction) through at least a part of the vertical extension portion 130f. Therefore, the upper end of the support portion 130 with which the contact protrusion 110c of the upward protrusion 111 is brought into contact when the elastic portion 150 is compressively deformed by the connection terminal 410 corresponds to an end of the vertical extension portion 130f. When the eccentric pressing force from the connection terminal 410 acts on the electrically conductive contact pin 100a according to the first embodiment, the contact protrusion 110c is supported through the vertical extension portion 130f. In the electrically conductive contact pin 100a according to the first embodiment, the upward protrusion 111 and the vertical extension portion 130f are located to correspond to each other in the width direction (+x direction), so when the eccentric pressing force is applied, the vertical extension portion 130f supports the upward protrusion 111. This prevents the electrically conductive contact pin 100a according to the first embodiment from being excessively buckled and deformed horizontally.

The support portion 130 is located to overlap the flange portion 160 in the width direction (±x direction) through at least a part of the vertical portion 130e. Due to the inclined extension portion IC1 inclinedly extending inward in the width direction (±x direction) from the end (lower end in the length direction (ty direction)) of the vertical portion 130e, a lower part of the support portion 130 is formed inclinedly.

When the elastic portion 150 is not compressed, the support portion 130 and the upward protrusion 111 of the first connection portion 110 are spaced apart from each other. In addition, the support portion 130 and the flange portion 160 located inside the support portion 130 are spaced apart from each other.

The support portion 130 includes a first support portion 130a located at a first side of the first connection portion 110, and a second support portion 130b located at a second side of the first connection portion 110.

The lower catch portion SP2 is connected to the support portion 130. The lower catch portion SP2 is provided at a position corresponding to at least a part of the inclined extension portion IC1 constituting the lower part of the support portion 130 in the width direction (tx direction) and is located at a lower part of the electrically conductive contact pin 100a according to the first embodiment. The lower catch portion SP2 includes a first lower catch portion 1003 provided at a position corresponding to a first inclined extension portion 2001 constituting a lower part of the first support portion 130a in the width direction (±x direction), and a second lower catch portion 1004 provided at a position corresponding to a second inclined extension portion 2002 constituting a lower part of the second support portion 130b in the width direction (±x direction).

The lower catch portion SP2 is compressed and deformed inward in the width direction (±x direction), inserted into a first side opening of a guide hole GH of a guide plate GP, and restored while passing through a second side opening of the guide hole GH and brought into contact with a lower surface of the guide plate GP so that the electrically conductive contact pin 100a according to the first embodiment is prevented from being separated in the direction of the first side opening.

The lower catch portion SP2 is inclinedly formed and includes an inclined portion IC2 inclined inward in the width direction (±x direction). The lower catch portion SP2 has a first end connected to an end of the inclined extension portion IC1 of the support portion 130. The lower catch portion SP2 may have a shape inclined outward in the width direction (±x direction) from the end of the inclined extension portion IC1.

The lower catch portion SP2 is inclined outward in the width direction (±x direction) from the end of the inclined extension portion IC1 and extends upward in the length direction (+y direction). The lower catch portion SP2 includes a shoulder portion 134b extending linearly from the inclined portion IC2 at a second end of the inclined portion IC2.

In other words, the lower catch portion SP2 is formed such that a first end of the inclined portion IC2 is connected to the end of the inclined extension portion IC1, and the shoulder portion 134b extending linearly upward (+y direction) from an end (specifically, the second end) of the inclined portion IC2 is provided at the second end of the inclined portion IC2. A second end of the lower catch portion SP2 provided with the shoulder portion 134b serves as a free end. The shoulder portion 134b of the lower catch portion includes a first shoulder portion 3001 forming a second end of the first lower catch portion 1003 and a second shoulder portion 3002 forming a second end of the second lower catch portion 1004.

The shoulder portion 134b has an upper surface inclined inward in the width direction (±x direction). Therefore, when compressing and deforming the lower part of the electrically conductive contact pin 100a according to the first embodiment inward in the width direction (±x direction) in order to insert the electrically conductive contact pin into the guide hole GH of the guide plate GP, the electrically conductive contact pin 100a can be elastically deformed more easily as the upper surface of the shoulder portion 134b is brought into close contact with the inclined extension portion IC1 of the support portion 130.

In the electrically conductive contact pin 100a according to the first embodiment, the first end of the lower catch portion SP2 and the first end of the inclined portion IC2 are connected to each other to integrally form the lower catch portion SP2 and the inclined extension portion IC1. With this, the lower part of the electrically conductive contact pin has a hook shape.

The electrically conductive contact pin 100a according to the first embodiment includes a cutout portion 134c between the lower catch portion SP2 and the inclined extension portion IC1. In the electrically conductive contact pin 100a according to the first embodiment, with the configuration of the cutout portion 134c, the lower catch portion SP2 is elastically deformed inward in the width direction (±x direction) so that the lower part of the electrically conductive contact pin 100a including the lower catch portion SP2 and the inclined extension portion IC1 is elastically deformed itself. When the electrically conductive contact pin 100a according to the first embodiment is inserted into the guide hole GH of the guide plate GP, the cut portion 134c enables the lower part of the electrically conductive contact pin 100a according to the first embodiment to be easily compressed deformed inward in the width direction (±x direction).

The electrically conductive contact pin 100a according to the first embodiment is provided in the guide hole GH in a manner of being inserted through the first side opening of the guide hole GH of the guide plate GP and passing through the second side opening vertically corresponding to the first side opening in the length direction (+y direction). Specifically, when the electrically conductive contact pin 100a according to the first embodiment is inserted into the guide hole GH, the lower part thereof including the lower catch portion SP2 and the inclined extension portion IC1 is compressed inward in the width direction (±x direction) and the second connection portion 120 is first inserted into the guide hole GH. At this time, due to the shape of the lower catch portion SP2 and the inclined extension portion IC1 inclined inward in the width direction (±x direction), the electrically conductive contact pin 100a according to the first embodiment can be easily compressed and deformed to have a smaller width in the width direction (±x direction) than the openings of the guide hole GH.

Then, the electrically conductive contact pin 100a according to the first embodiment is forcibly pushed into the guide hole GH by pressing the electrically conductive contact pin 100a downward. The electrically conductive contact pin 100a according to the first embodiment is compressed in the width direction (±x direction) and moved to a lower part of the guide hold GH. When the lower part of the electrically conductive contact pin 100a according to the first embodiment passes through the second side opening of the guide hole GH, the lower catch portion SP2 is restored, and accordingly the electrically conductive contact pin is pushed upward (+y direction) until the upper surface of the second end of the lower catch portion SP2 is supported by the lower surface of the guide hole GH.

Specifically, when the lower part of the electrically conductive contact pin 100a according to the first embodiment passes through the second side opening of the guide hole GH, the lower catch portion SP2 is restored outward in the width direction (±x direction). Therefore, the lower catch portion SP2 corresponds to the lower surface of the guide plate GP. Then, the electrically conductive contact pin 100a according to the first embodiment is pushed upward (+y direction) until the upper surface of the shoulder portion 134b provided at the second end of the lower catch portion SP2 is brought into contact with and supported by the lower surface of the guide hole GH.

When the lower part of the electrically conductive contact pin 100a according to the first embodiment passes through the second side opening of the guide hole GH, as the lower catch portion SP2 is restored outward in the width direction (±x direction), a width in width direction (±x direction) between the first shoulder portion 3001 of the first lower catch portion 1003 connected to an end of the first support portion 130a and the second shoulder portion 3002 of the second lower catch portion 1004 connected to an end of the second support portion 130b becomes larger than a width of the second side opening of the guide hole GH.

Therefore, the shoulder portion 134b of the lower catch portion SP2 is located corresponding to the lower surface of the guide hole GH, moved upward (+y direction) by a predetermined distance in the length direction (ty direction), and brought into contact with and supported by the lower surface of the guide hole GH.

When the lower catch portion SP2 is brought into contact with and supported by the lower surface of the guide hole GH, the electrically conductive contact pin 100a according to the first embodiment is fixed in position in a state in which it is no longer moved upward (±y direction). Therefore, the electrically conductive contact pin 100a according to the first embodiment can be prevented from being separated in the upward direction (±y direction), that is, in the direction in which the first side opening of the guide hole GH is located.

When the electrically conductive contact pin 100a according to the first embodiment is excessively compressed and deformed by the connection terminal 410 and a pad 310, the lower catch portion SP2 may function to buffer the electrically conductive contact pin 100a in the length direction (±y direction).

Specifically, with the shoulder portion 134b of the lower catch portion SP2 being in contact with and supported by the lower surface of the guide plate GP, the electrically conductive contact pin 100a according to the first embodiment is compressed and deformed from upward (±y direction) to downward (−y direction) by the connection terminal 410, and is compressed and deformed from downward (−y direction) to upward (±y direction) by the pad 310. The lower catch portion SP2 is elastically deformable in the width direction (±x direction) and the length direction (ty direction).

The lower catch portion SP2 is elastically deformable in the width direction (±x direction) and the length direction (ty direction). Therefore, the lower catch portion SP2 has an elastic restoring force in the width direction (±x direction) and the length direction (ty direction). When the electrically conductive contact pin 100a according to the first embodiment is excessively compressed and deformed, the lower catch portion SP2 exerts the elastic restoring force in the length direction (±y direction) while being in contact with and supported by the lower surface of the guide plate GP. The lower catch portion SP2 may perform a buffering function by exerting the elastic restoring force to weaken excessive compressive strain applied to the electrically conductive contact pin 100a according to the first embodiment in the length direction (±y direction).

When the lower catch portion SP2 is brought into contact with and supported by the lower surface of the guide hole GH, an upper part of the electrically conductive contact pin 100a according to the first embodiment including the upper catch portion SP1 is provided in a state of protruding from the upper surface of the guide plate GP.

The upper catch portion SP1 prevents the electrically conductive contact pin 100a according to the first embodiment from being separated downward (−y direction, in the direction of the second side opening).

The upper catch portion SP1 is connected to the support portion 130. Specifically, the upper catch portion is provided at a position corresponding to at least a part (specifically, an upper part) of the vertical portion 130e of the support portion 130 in the width direction (±x direction). The upper catch portion SP1 is provided by a portion that protrudes outward in the width direction (±x direction) from an outer surface of the upper part of the vertical portion 130e of the support portion 130. The upper catch portion SP1 is connected to the vertical portion 130e of the support portion 130.

The upper catch portion SP1 includes a first upper catch portion 1001 provided at the first support portion 130a and a second upper catch portion 1002 provided at the second support portion 130b. Specifically, the vertical portion 130e includes a first vertical portion 4001 of the first support portion 130a and a second vertical portion 4002 of the second support portion 130b. The first upper catch portion 1001 corresponds to at least a part (specifically, an upper part) of the first vertical portion 4001 of the first support portion 130a in the width direction (±x direction). The second upper catch portion 1002 corresponds to at least a part (specifically, an upper part) of the second vertical portion 4002 of the second support portion 130b in the width direction (±x direction).

In the electrically conductive contact pin 100a according to the first embodiment, a dimension in the width direction (±x direction) at a position provided with the upper catch portion SP1 is larger than a width dimension of the first side opening of the guide hole GH into which the lower part of the electrically conductive contact pin 100a according to the first embodiment is first inserted. In other words, a dimension in the width direction (±x direction) between the first upper catch portion 1001 connected to the first support portion 130a and the second upper catch portion 1002 connected to the second support portion 130b is larger than the width dimension of the first side opening of the guide hole GH. With this, the electrically conductive contact pin 100a according to the first embodiment can be prevented from being separated in the direction of the second side opening through the upper catch portion SP1.

In the electrically conductive contact pin 100a according to the first embodiment, a length of the support portions 130 is formed longer than that of the guide hole GH. Therefore, when insertion of the electrically conductive contact pin into the guide hole GH is completed, at least a part of the support portion 130 protrudes outward from the guide hole GH in the length direction (±y direction).

Specifically, at least a part of the vertical portion 130e and the vertical extension portion 130f of the support portion 130 protrude outward from the first side opening of the guide hole GH, and at least a part of the inclined extension portion IC1 of the support portion 130 protrudes outward from the lower part of the guide hole GH. The support portion 130 includes the vertical extension portion 130f extending and protruding beyond the upper catch portion SP1 in the length direction (ty direction). Therefore, the vertical extension portion 130f is located higher than the upper catch portion SP1 in the length direction (ty direction) and protrudes outward from the guide hole GH.

At this time, the lower catch portion SP2 provided at a position corresponding to the inclined extension portion IC1 in the width direction (±x direction) is brought into contact with the lower surface of the guide plate GP.

Meanwhile, as at least the part of the vertical portion 130e of the support portion 130 protrudes outward from first side opening of the guide hole GH, the electrically conductive contact pin 100a according to the first embodiment has a protruding length h defined as a length between the upper catch portion SP1 and the upper surface of the guide plate GP.

Due to the protruding length h, the electrically

conductive contact pin 100a according to the first embodiment secures contact stroke of the test object 400. Due to the protruding length h, the electrically conductive contact pin 100a according to the first embodiment secures a free space corresponding to the protruding length h with respect to the first side opening of the guide hole GH formed around the upper surface of the guide plate GP. With this, when the electrically conductive contact pin 100a according to the first embodiment is pressed by the connection terminal 410 and moved downward, the electrically conductive contact pin 100a according to the first embodiment can be entirely moved downward within the free space provided by the protruding length h.

When the connection terminal 410 is moved downward to be brought into contact with the electrically conductive contact pin 100a according to the first embodiment, stroke may not be constant. Therefore, when the protruding length h between the upper catch portion SP1 and the upper surface of the guide plate GP is not secured as the support portion 130 protrudes from the guide hole GH and accordingly the free space is not provided between the upper catch portion SP1 and the guide plate GP, the electrically conductive contact pin 100a according to the first embodiment may be excessively pressed. This may cause damage to the electrically conductive contact pin 100a according to the first embodiment.

However, in the electrically conductive contact pin 100a according to the first embodiment, the upper part of the vertical portion 130e of the support portion 130 protrudes from the guide hole GH, and the protruding length h is formed between the upper catch portion SP1 that protrudes outward from the outer surface of the upper part of the vertical portion 130e in the width direction (±x direction) and the upper surface of the guide plate GP. Due to the protruding length h, the electrically conductive contact pin 100a according to the first embodiment secures contact stroke.

With this, after making first contact with the connection terminal 410, the electrically conductive contact pin 100a according to the first embodiment can be entirely moved downward through the protruding length h between the surface of the guide upper catch portion SP1 and the upper plate GP, thereby being prevented from being damaged.

The protruding length h may be in the range of 5 μm to 50 μm. When the protruding length h is less than 5 μm, it is difficult to secure contact stroke of the test object, and when it exceeds 50 μm, there is a possibility of causing excessive deformation of the contact pin 100a or damage to the support portion 130.

The stopper portion 170 is formed to extend from the inner surface of the support portion 130 by a predetermined length inward in the width direction (±x direction). The stopper portion 170 is formed to have a width that gradually decreases from the inner surface of the support portion 130 inward in the width direction (±x direction). The stopper portion 170 extends inward in the width direction from the inner surface of the support portion 130 and is connected to the elastic portion 150.

Specifically, the stopper portion 170 is provided at the same position in the length direction as at least one of the curved portions 154 of the elastic portion 150 close to the second connection portion 120 and has an end connected to the curved portion 154.

The stopper portion 170 is provided below the flange portion 160. Before the elastic portion 150 is compressed and deformed, the stopper portion 170 is spaced apart from lower surface of the flange portion 160. When the elastic portion 150 is compressed and deformed, the flange portion 160 is moved downward (−y direction). The stopper portion 170 is brought into contact with the downward moving flange portion 160 to limit a downward movement position of the flange portion 160.

The stopper portion 170 includes a first stopper portion 170a provided at the first side of the elastic portion 150, and a second stopper portion 170b provided at the second side of the elastic portion 150 oppositely to the first stopper portion 170a. The first stopper portion 170a and the second stopper portion 170b are respectively connected to opposite ends of the same straight portion 153 and provided at the same position in the length direction.

In the electrically conductive contact pin 100a according to the first embodiment, the elastic portion 150 and the first support portion 130a are connected to each other through the first stopper portion 170a, and the elastic portion 150 and the second support portion 130b are connected to each other through the second stopper portion 170b.

The first stopper portion 170a is provided below the first flange portion 160a so as to correspond vertically to the first flange portion 160a in the length direction, and the second stopper portion 170b is provided below the second flange portion 160b so as to correspond vertically to the second flange portion 160b in the length direction.

When lower surfaces of the first and second flange portions 160a and 160b are brought into contact with upper surfaces of the first and second stopper portions 170a and 170b, respectively, the first and second stopper portions support and stop the first and second flange portions 160a and 160b so that the first and second flange portions 160a and 160b are not moved further downward.

The first flange portion 160a is brought into contact with a relatively flat bottom surface of the first stopper portion 170a.

Meanwhile, the second flange portion 160b is brought into contact with a curved surface of the second stopper portion 170b, which has a relatively larger degree of curvature than the first stopper portion 170a, in the length direction (±y direction) and the width direction (±x direction) and is deformed by a predetermined amount.

The electrically conductive contact pin 100a according to the first embodiment is divided into an upper space US and a lower space LS through the stopper portion (specifically, the first and second stopper portions 170a and 170b). Therefore, the electrically conductive contact pin 100a according to the first embodiment can prevent foreign substances introduced from above from flowing into the lower space LS, and prevent foreign substances introduced from below from flowing into the upper space US. By restricting the movement of foreign substances introduced into the electrically conductive contact pin 100a according to the first embodiment through the stopper portion 170, the electrically conductive contact pin 100a can prevent problems of operation interference caused by foreign substances.

The second connection portion 120 is provided between the first inclined extension portion 2001 and the second inclined extension portion 2002. Therefore, the second connection portion 120 is provided inside a lower end of the support portion 130 in the width direction (±x direction).

The second connection portion 120 is brought into contact with the pad 310 of a circuit board.

The second connection portion 120 includes a connection body 120a, a connection cavity 120d formed in the connection body 120a, and at least one pad connection protrusion 120c provided on a lower surface of the connection body 120a.

The connection body 120a includes a connection inclined portion CI inclined inward in the width direction (±x direction) and inclined in an inclined direction of the inclined extension portion IC1, and a connection vertical portion CV extending vertically downward from an end of the connection inclined portion CI in the length direction (±y direction).

With the configuration of the connection cavity 120d, a contact surface of the second connection portion 120 can be more easily deformed by pressure of the pad 310 of the circuit board.

The second connection portion 120 includes at least one pad connection protrusion 120c to make multi-contact with the pad 310 of the circuit board located below the connection body 120a. The pad connection protrusion 120c is formed along the thickness direction (+z direction) of the connection body 120a, and is formed to protrude and extend in the length direction (ty direction) beyond its surrounding portion.

As an example, three pad connection protrusions 120c are provided. Among the three pad connection protrusions 120c, two pad connection protrusions 120c on outer peripheral sides are formed to be inclined outward in the width direction (±x direction). The pad connection protrusions 120c are spaced apart from each other by depressions 121 provided between the pad connection protrusions 120c.

Referring to FIG. 6, when testing the test object 400, the connection terminal 410 of the test object 400 is moved downward (−y direction) while being brought into contact sequentially with the upper surface of the first connection portion 110 and the upper surface of the upward protrusion 111. Specifically, the connection terminal 410 is brought into contact with the upper surface of the first connection portion 110 first and then brought into contact with the inclined upper surface of the upward protrusion 111 while compressing and deforming the elastic portion 150. The connection terminal 410 is moved downward while being in contact with the upper surface of the first connection portion 110 and the upper surface of the contact protrusion 110c of the upward protrusion 111. As the first connection portion 110 and the upward protrusion 111 are gradually moved downward, the contact protrusion 110c is brought into contact with the upper end of the support portion 130. As a result, the electrically conductive contact pin 100b according to the first embodiment forms a current path extending connecting the first connection portion 110 and the support portion 130.

When the elastic portion 150 connected to the second connection portion 120 is compressed and deformed upward by a pressing force of the pad 310 of the circuit board and moved upward, the connection vertical portion CV of the connection body 120a and a portion where the inclined extension portion IC1 and the inclined portion IC2 are connected are brought into contact with each other. As a result, the electrically conductive contact pin 100a according to the first embodiment forms a current path extending connecting the second connection portion 120 and the support portion 130.

Hereinafter, a method of manufacturing the electrically conductive contact pin 100a according to the first embodiment will be described.

FIG. 7a is a plan view illustrating the mold 1000 in which the inner space 1100 is formed. FIG. 7b is a sectional view taken along line A-A′ of FIG. 7a.

The mold 1000 may be made of an anodic aluminum oxide film, a photoresist, a silicon wafer, or a material similar thereto. However, a preferred material for the mold 1000 is the anodic aluminum oxide film. The anodic aluminum oxide film refers to a film formed by anodization of a metal as a base material, and pores refer to holes formed in the process of forming the anodic aluminum oxide film by the anodization of the metal. For example, when the metal as the base material is aluminum (Al) or an aluminum alloy, the anodization of the base material forms an anodic aluminum oxide film consisting of anodized aluminum (Al₂O₃) on a surface of the base material.

However, the metal as the base material is not limited thereto, and includes Ta, Nb, Ti, Zr, Hf, Zn, W, Sb, or an alloy of these metals. The resulting anodic aluminum oxide film includes a barrier layer in which no pores are formed therein vertically, and a porous layer in which pores are formed therein. After removing the base material on which the anodic aluminum oxide film including the barrier layer and the porous layer is formed, only the anodic aluminum oxide film consisting of anodized aluminum (Al₂O₃) remains. The anodic aluminum oxide film may have a structure in which the barrier layer formed during the anodization is removed to expose the top and bottom of the pores, or a structure in which the barrier layer formed during the anodization remains to close one of the top and bottom of the pores.

The anodic aluminum oxide film has a coefficient of thermal expansion of 2 to 3 ppm/° C. With this range, the anodic aluminum oxide film only undergoes a small amount of thermal deformation due to temperature when exposed to a high-temperature environment. Therefore, even when the electrically conductive contact pin 100a is manufactured in a high-temperature environment, a precise electrically conductive contact pin 100a can be manufactured without thermal deformation.

Since the electrically conductive contact pin 100a according to the first embodiment is manufactured using the mold 1000 made of the anodic aluminum oxide film instead of a photoresist mold, there is an effect of realizing shape precision and a fine shape, which were limited in realization with the photoresist mold. In addition, when the conventional photoresist mold is used, an electrically conductive contact pin with a thickness of 40 μm can be manufactured, but when the mold 1000 made of the anodic aluminum oxide film is used, the electrically conductive contact pin 100a with a thickness in the range of 100 μm to 200 μm can be manufactured.

A seed layer 1200 is provided on a lower surface of the mold 1000. The seed layer 1200 may be provided on the lower surface of the mold 1000 before the inner space 1100 is formed in the mold 1000. Meanwhile, a support substrate (not illustrated) is formed under the mold 1000 to improve handling of the mold 1000. In this case, the seed layer 1200 may be formed on an upper surface of the support substrate, and then the mold 1000 having the inner space 1100 may be coupled to the support substrate. The seed layer 1200 may be made of copper (Cu), and may be formed by a deposition method.

The inner space 1100 may be formed by wet-etching the mold 1000 made of the anodic aluminum oxide film. To this end, a photoresist may be provided on the upper surface of the mold 1000 and patterned, and then the anodic aluminum oxide film in a patterned and open area may react with an etchant to form the inner space 1100.

Thereafter, an electroplating process is performed on the inner space 1100 of the mold 1000 to form an electrically conductive contact pin 100a. FIG. 7c is a plan view illustrating the electroplating process performed on the inner space 1100. FIG. 7d is a sectional view taken along line A-A′ of FIG. 7c.

During the electroplating process, a metal layer is formed while growing in the thickness direction (+z direction) of the mold 1000. Therefore, the metal layer thus formed has a uniform cross-sectional shape in the thickness direction (+z direction) of the electrically conductive contact pin 100a. A plurality of metal layers are stacked in the thickness direction (+z direction) of the electrically conductive contact pin 100a. The plurality of metal layers include a first metal layer 101 and a second metal layer 102. The first metal layer 101 is a metal having relatively high wear resistance compared to the second metal layer 102, and may be selected from the group consisting of rhodium (Rd), platinum (Pt), iridium (Ir), palladium, and an alloy of these metals; the group consisting of a palladium-cobalt (PdCo) alloy and a palladium-nickel (PdNi) alloy; or the group consisting of a nickel-phosphor (NiPh) alloy, a nickel-manganese (NiMn) alloy, a nickel-cobalt (NiCo) alloy, and a nickel-tungsten (NiW) alloy. The second metal layer 102 is a metal having relatively high electrical conductivity compared to the first metal layer 101, and may be selected from the group consisting of copper (Cu), silver (Ag), gold (Au), and an alloy of these metals.

The first metal layer 101 is provided on each of a lower surface and an upper surface of the electrically conductive contact pin 100a in the thickness direction (+z direction), and the second metal layer 102 is provided between the respective first metal layers 101. For example, the electrically conductive contact pin 100a may be provided by sequentially stacking the first metal layer 101, the second metal layer 102, and the first metal layer 101, and the number of stacked layers may be at least three.

Meanwhile, after the plating process is completed, the temperature is raised to a high temperature and pressure is applied to pressurize the metal layers on which the plating process is completed so that the first metal layer 101 and the second metal layer 102 are made denser. When a photoresist is used as a mold, the process of raising the temperature to a high temperature and applying pressure cannot be performed because the photoresist exists around the metal layers after the plating process is completed. On the contrary, according to the preferred embodiment of the present disclosure, since the mold 1000 made of the anodic aluminum oxide film is provided around the metal layers on which the plating process is completed, even when the temperature is raised to a high temperature, it is possible to densify the first metal layer 101 and the second metal layer 102 with minimized deformation because of the low coefficient of thermal expansion of the anodic aluminum oxide film. Therefore, it is possible to obtain the first metal layer 101 and the second metal layer 102 with a higher density compared to the technique using the photoresist as a mold.

When the electroplating process is completed, the mold 1000 and the seed layer 1200 are removed. When the mold 1000 is made of the anodic aluminum oxide film, the mold 1000 is removed using a solution that selectively reacts with the anodic aluminum oxide film. In addition, when the seed layer 1200 is made of copper (Cu), the seed layer 1200 is removed using a solution that selectively reacts with copper (Cu).

Referring to FIG. 8, the electrically conductive contact pins 100a according to the first embodiment includes a plurality of fine trenches 88 provided on a side surface thereof. The fine trenches 88 are formed to extend in the thickness direction (+z direction) of the electrically conductive contact pin 100a on the side surface of the electrically conductive contact pin 100a. Here, the thickness direction (+z direction) of the electrically conductive contact pin 100a refers to a direction in which a metal filling material grows during electroplating.

The fine trenches 88 have a depth in the range of 20 nm to 1 μm and a width in the range of 20 nm to 1 μm. Here, because the fine trenches 88 are resulted from the formation of the pores formed during the manufacture of the mold 1000 made of the anodic aluminum oxide film, the width and depth of the fine trenches 88 are equal to or less than the diameter of the pores formed in the mold 1000 made of the anodic aluminum oxide film. Meanwhile, in the process of forming the inner space 1100 in the mold 1000 made of the anodic aluminum oxide film, portions of the pores of the mold 1000 made of the anodic aluminum oxide film may be crushed by an etchant to at least partially form a fine trench 88 having a depth larger than the diameter of the pores formed during the anodization.

Since the mold 1000 made of the anodic aluminum oxide film includes a large number of pores, at least a part of the mold 1000 made of the anodic aluminum oxide film is etched to form the inner space 1100, and the metal filling material is formed in the inner space 1100 by electroplating, the fine trenches 88 are formed on the side surface of the electrically conductive contact pin 100a as a result of contact between the contact pin and the pores of the mold 1000 made of the anodic aluminum oxide film.

The fine trenches 88 as described above can contribute to increasing the surface area of the side surface of the electrically conductive contact pin 100a. In addition, with the configuration of the fine trenches 88 formed on the side surface of the electrically conductive contact pin 100a, heat generated in the electrically conductive contact pin 100a can be rapidly dissipated, thereby suppressing a rise in the temperature of the electrically conductive contact pin 100a. In addition, with the configuration of the fine trenches 88 formed on the side surface of the electrically conductive contact pin 100a, the torsional resistance ability of the electrically conductive contact pin 100a against deformation can be improved.

In order to effectively cope with the test of high-frequency characteristics of the test object 20, the overall length L of the electrically conductive contact pin 100a has to be short. Therefore, the length of the elastic portion 150 has to also be shortened. However, when the length of the elastic portion 150 is shortened, a problem occurs in that contact pressure increases. In order to shorten the length of the elastic portion 150 without increasing the contact pressure, the actual width t of the plate constituting the elastic portion 150 has to be small. However, when the actual width t of the plate constituting the elastic portion 150 is shortened, a problem occurs in that the elastic portion 150 tends to be damaged. In order to shorten the length of the elastic portion 150 without increasing the contact pressure and prevent damage to the elastic portion 150, the overall thickness H of the plate constituting the elastic portion 130 has to be large.

The electrically conductive contact pin 100a according to the first embodiment is formed such that the actual width t of the plate is small while the overall thickness H of the plate is large. In other words, the overall thickness H of the plate is configured to be large compared to the actual width t thereof. Preferably, the actual width t of the plate constituting the electrically conductive contact pin 100a is in the range of 5 μm to 15 μm, the overall thickness H thereof is in the range of 70 μm to 200 μm, and the actual width t and the overall thickness H of the plate have a ratio in the range of 1:5 to 1:30. For example, the actual width t of the plate may be substantially 10 μm, and the overall thickness H thereof may be 100 μm, so that the actual width t and the overall thickness H of the plate may have a ratio of 1:10.

With this, it is possible to shorten the length of the elastic portion 150 while preventing damage to the elastic portion 150, and it is possible for the elastic portion 150 to have an appropriate contact pressure even when the length thereof is shortened. Furthermore, as it is possible to increase the overall thickness H of the plate constituting the elastic portion 150 compared to the actual width t thereof, the resistance to moments acting in the front and rear directions of the elastic portion 150 is increased, resulting in improved contact stability.

As it is possible to shorten the length of the elastic portion 150, the overall thickness H and the overall length L of the electrically conductive contact pin 100a have a ratio in the range of 1:3 to 1:9. Preferably, the overall length L of the electrically conductive contact pin 100a is in the range of 300 μm to 2 mm, and more preferably 350 μm to 600 μm. As such, as it is possible to shorten the overall length L of the electrically conductive contact pin 100a, it is possible to effectively cope with high-frequency characteristics. Also, the elastic recovery time of the elastic portion 150 is shortened, thereby shortening the test time.

In addition, as the actual width t of the plate constituting the electrically conductive contact pin 100a is configured to be smaller than the overall thickness H thereof, bending resistance in the front and rear directions can be improved.

The overall thickness H and the overall width W of the electrically conductive contact pin 100a according to the first embodiment have a ratio in the range of 1:1 to 1:5. Preferably, the overall thickness H of the electrically conductive contact pin 100a is in the range of 70 μm to 200 μm, and the overall width W of the electrically conductive contact pin 100a is in the range of 100 μm to 500 μm. More preferably, the overall width W of the electrically conductive contact pin 100a is in the range of 150 μm to 400 μm. By shortening the overall width W of the electrically conductive contact pin 100a as described above, it is possible to implement a narrower pitch.

Meanwhile, the overall thickness H and the overall width W of the electrically conductive contact pin 100a according to the first embodiment may be configured to be substantially the same. Therefore, it is not necessary to join a plurality of separately manufactured electrically conductive contact pins 100a in the thickness direction (+z direction) so that the overall thickness H and the overall width W become substantially the same. In addition, as it is possible to make the overall thickness H and the overall width W of the electrically conductive contact pin 100a substantially the same, the resistance to moments acting in the front and rear directions of the electrically conductive contact pin 100a is increased, resulting in improved contact stability.

Furthermore, with the configuration in which the overall thickness H of the electrically conductive contact pin 100a is equal to or larger than 70 μm and the ratio of the overall thickness H to the overall width W thereof is in the range of 1:1 to 1:5, overall durability and deformation stability of the electrically conductive contact pin 100a can be improved and thereby contact stability with the connection terminal 410 can be improved. In addition, as the overall thickness H of the electrically conductive contact pin 100a is configured to be equal to or larger than 70 μm, current carrying capacity can be improved.

A conventional electrically conductive contact pin 100a manufactured using a photoresist mold cannot have a large overall thickness due to alignment problems because the mold is formed by stacking a plurality of photoresists. As a result, the conventional electrically conductive contact pin has a smaller overall thickness H compared to an overall width W. For example, in the case of the conventional electrically conductive contact pin 100a, the overall thickness H may be less than 70 μm and the overall thickness H and the overall width W may have a ratio in the range of 1:2 to 1:10.

Therefore, the resistance to moments that deform the electrically conductive contact pin 100a in the front and rear directions by contact pressure is weak. Conventionally, in order to prevent problems occurring due to excessive deformation of the elastic portion on front and rear surfaces of the electrically conductive contact pin 100a, it should be considered to additionally form a housing on the front and rear surfaces of the electrically conductive contact pin 100a. However, according to the preferred embodiment of the present disclosure, an additional housing is not necessary.

### Second Embodiment

Next, a second embodiment according to the present disclosure will be described. However, the embodiments described below will be mainly described in terms of characteristic elements in comparison with the first embodiment, and descriptions of the same or similar elements to the first embodiment will be omitted.

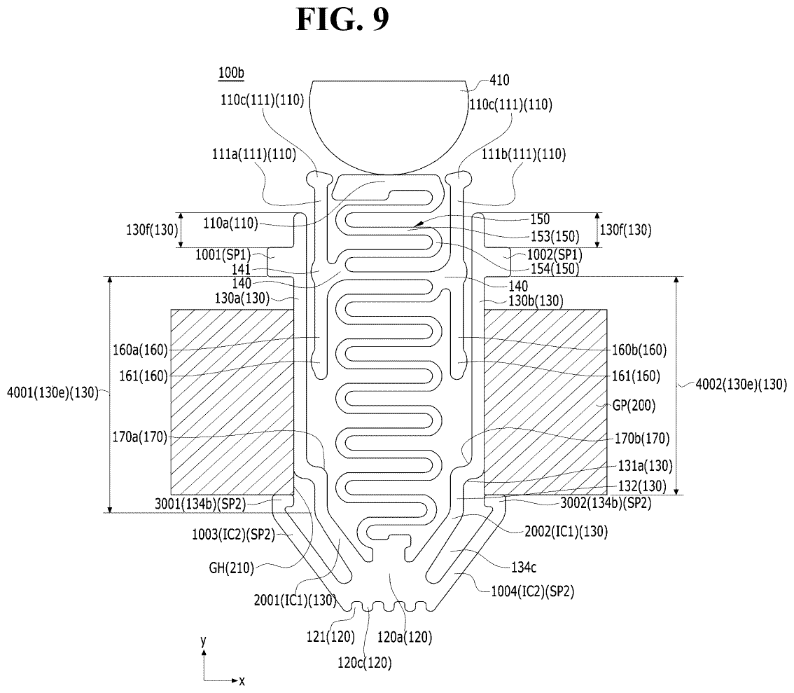

Hereinafter, an electrically conductive contact pin according to a second preferred embodiment of the present disclosure (hereinafter referred to as “electrically conductive contact pin 100b according to the second embodiment”) will be described with reference to FIG. 9. FIG. 9 is a view illustrating an electrically conductive contact pin 100b according to the second embodiment is installed in an installation member 200 (guide plate GP).

The electrically conductive contact pin 100b according to the second embodiment is different from the electrically conductive contact pin 100a according to the first embodiment in that a second connection portion 120 is connected to a lower catch portion SP2.

The electrically conductive contact pin 100b according to the second embodiment includes a first connection portion 110 including a contact portion 110a and an upward protrusion 111, a second connection portion 120 including a connection body 120a and a pad connection protrusion 120c, a lower catch portion SP2 connected to the second connection portion 120, a support portion 130 including an inclined extension portion IC1, an upper catch portion SP1 connected to the support portion 130, a flange portion 160, and a stopper portion 170.

The support portion 130 includes a vertical portion 130e formed by bending inward in the width direction (±x direction) of the electrically conductive contact pin 100a toward a second end (lower end) thereof. The support portion 130 includes a first width deformation portion 131a provided at the second end of the vertical portion 130e and reducing a distance between support portions 130 in the width direction (±x direction), and the inclined extension portion IC1 provided at a lower part of the width deformation portion 131a and inclined inward in the width direction (±x direction) toward an end thereof. The support portion 130 includes a width deformation connection portion 132 connecting the first width deformation portion 131a and the inclined extension portion 131b between the first width deformation portion 131a and the inclined extension portion IC1.

In the electrically conductive contact pin 100b according to the second embodiment, through the first width deformation portion 131a provided on at least a part of the support portion 130 (specifically, the second end of the vertical portion 130e of the support portion 130), a recessed portion is formed inward in the width direction (±x direction) at the second end of the vertical portion 130e of the support portion 130. In the electrically conductive contact pin 100b according to the second embodiment, the stopper portion 170 is provided through the recessed portion.

In other words, the stopper portion 170 is formed integrally with the support portion 130 on at least a part (lower part) of the support portion 130 by a portion recessed inward in the width direction (±x direction) by the first width deformation portion 131a. The first width deformation portion 131a is a portion recessed from a lower outer surface of the support portion 130 inward in the width direction (±x direction).

In the electrically conductive contact pin 100b according to the second embodiment, a lower inner surface of the support portion 130 is formed to protrude inward in the (+x width direction direction) along the first width deformation portion 131a at a position corresponding to the first width deformation portion 131a. A portion protruding inward in the width direction (±x direction) from the lower inner surface of the support portion 130 is formed to have a thickness in the width direction (±x direction) equal to a length protruding inward from the inner surface of the support portion 130 in the width direction (±x direction). In the electrically conductive contact pin 100b according to the second embodiment is, the stopper portion 170 is provided through the portion protruding inward in the width direction (tx direction) from the lower inner surface of the support portion 130 by the first width deformation portion 131a.

A first stopper portion 170a is provided at a lower part of a first vertical portion 4001 of a first support portion 130a and corresponds vertically to a first flange portion 160a in length direction (ty direction). A second stopper portion 170b is provided at a lower part of a second vertical portion 4002 of a second support portion 130b and corresponds vertically to a second flange portion 160b in the length direction (±y direction).

The first and second flange portions 160a and 160b are moved downward (−y direction) due to compressive deformation of an elastic portion 150.

The first and second flange portions 160a and 160b are moved downward while gradually reducing a separation distance R between the flange portion 160 and the stopper portion 170 before compressive deformation of the elastic portion 150 and brought into contact with upper surfaces of the first and second stopper portions 170a and 170b. With lower surfaces of the first and second flange portions 160a and 160b being in contact with the upper surfaces of the first and second stopper portions 170a and 170b, the first and second stopper portions support the first and second flange portions 160a and 160b to prevent the first and second flange portions from moving further downward, thereby limiting a downward movement position of the first and second flange portions 160a and 160b.

The inclined extension portion 131b of the support portion 130 has an end connected to the second connection portion 120. The second connection portion 120 includes the connection body 120a having a predetermined thickness in the length direction (ty direction). The connection body 120a is formed to increase in width from an upper part toward a lower part thereof in the width direction. The connection body 120a has an upper surface connected to the elastic portion 150. The end of the inclined extension portion 131b is connected to an upper outer surface of the second connection portion 120.

The lower catch portion SP2 is connected to a lower outer surface of the connection body 120a of the second connection portion 120 through an inner surface of an end (specifically, a first end) of an inclined portion IC2.

A shoulder portion 134b is formed to protrude inward in the width direction from a second end of the inclined portion IC2. The shoulder portion 134b has an upper surface formed as a flat surface.

The electrically conductive contact pin 100b according to the second embodiment is provided in a guide hole GH in a manner of being inserted through a first side opening of the guide hole GH and passing through a second side opening thereof. When a lower part of the electrically conductive contact pin 100b according to the second embodiment passes through the second side opening of the guide hole GH, the lower catch portion SP2 is restored. At this time, the upper surface of the shoulder portion 134b of the lower catch portion SP2 corresponds to a lower surface of the guide plate GP.

After the lower catch portion SP2 is restored, the electrically conductive contact pin 100b according to the second embodiment is pushed upward (±y direction) until the upper surface of the shoulder portion 134b is brought into contact with and supported by the lower surface of the guide plate GP. Therefore, the upper surface of the shoulder portion 134b is supported in contact with the lower surface of the guide plate GP. In the electrically conductive contact pin 100b according to the second embodiment, by forming the upper surface of the shoulder portion 134b to be flat, close contact is more effectively achieved after contact with the lower surface of the guide plate GP.

The electrically conductive contact pin 100b according to the second embodiment is brought into contact with and supported by the lower surface of the guide plate GP through the shoulder portion 134b of the lower catch portion SP2, thereby being prevented from being separated in the direction of the first side opening.

As an example, the second connection portion 120 includes four pad connection protrusions 120c. The pad connection protrusions 120c are spaced apart from each other by depressions 121 provided between the pad connection protrusions 120c. Among the four pad connection protrusions 120c, two pad connection protrusions 120c on peripheral sides are provided through an end (specifically, a first end not provided with the shoulder portion 134b) of the inclined portion IC2 of the lower catch portion SP2.

The second connection portion 120 is brought into contact with and pressed against a pad 310 of a circuit board through the pad connection protrusions 120c.

As a connection terminal 410 compresses and deforms the elastic portion 150 connected to the first connection portion 110, a contact protrusion 110c of the upward protrusion 111 is brought into contact with the support portion 130, and the pad 310 is brought into contact with the pad connection protrusions 120c of the second connection portion 120, causing the elastic portion 150 connected to the second connection portion 120 to be compressed and deformed. As a result, the electrically conductive contact pin 100a according to the second embodiment forms a current path connecting the first connection portion 110, the support portion 130, and the second connection portion 120.

### Third Embodiment

Next, a third embodiment according to the present disclosure will be described. However, the embodiments described below will be mainly described in terms of characteristic elements in comparison with the first embodiment, and descriptions of the same or similar elements to the first embodiment will be omitted.

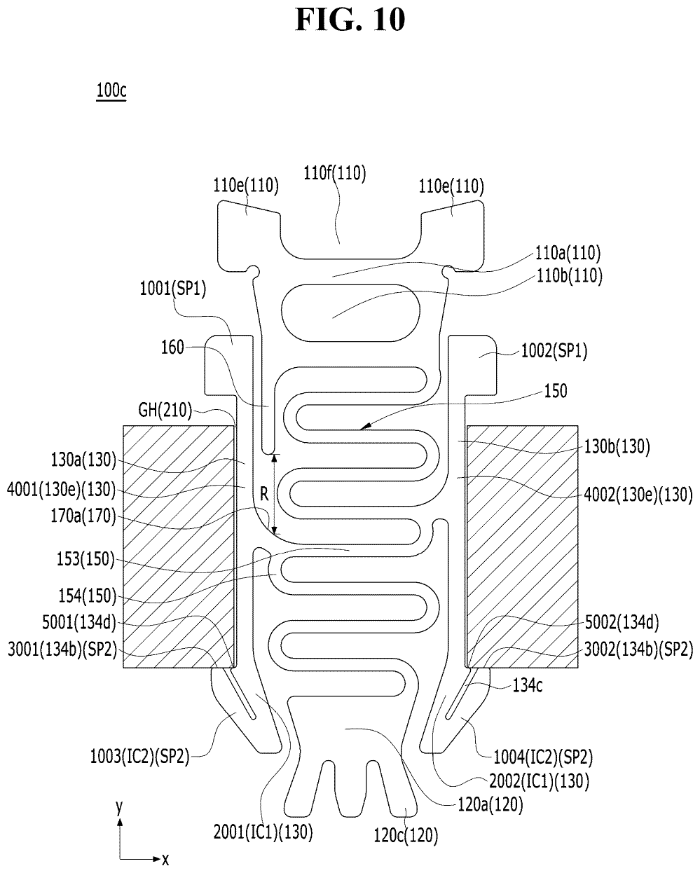

Hereinafter, an electrically conductive contact pin according to a third preferred embodiment of the present disclosure (hereinafter referred to as “electrically conductive contact pin 100c according to the third embodiment”) will be described with reference to FIG. 10.

FIG. 10 is a view illustrating an electrically conductive contact pin 100c according to the second embodiment is installed in an installation member 200 (specifically, a guide plate GP).

The electrically conductive contact pin 100c according to the third embodiment includes a first connection portion 110 including a contact portion 110a in which a contact cavity 110b is formed, the contact cavity 110b formed in the contact portion 110a, a contact protrusion 110e extending in the length direction (ty direction) from an upper surface of the contact cavity 110b; a second connection portion 120 including a connection body 120a and a pad connection protrusion 120c; a support portion 130 including a vertical portion 130e and an inclined extension portion IC1; an elastic portion 150; a lower catch portion SP2 connected to the support portion 130; an upper catch portion SP1 connected to the support portion 130; a flange portion 160 extending in the length direction (±y direction) from a lower surface of the first connection portion 110 and connected to the first connection portion 110; and a stopper portion 170.

The first connection portion 110 includes the contact protrusion 110e extending upward from an end in the width direction (±x direction) of the contact portion 110a having the contact cavity 110b formed at a center thereof. The electrically conductive contact pin 100c according to the third embodiment has two contact protrusions 110e. The contact protrusions 110e are formed to protrude outward from the contact portion 110a in the width direction (±x direction). Each of the contact protrusions 110e has an inclined upper surface. The upper surfaces of the contact protrusions 110e are inclined downward from an outer side to an inner side in the width direction (±x direction). With this, particles generated during repeated contact between a connection terminal 410 and the electrically conductive contact pin 100c according to the third embodiment can easily be moved toward a depression portion 110f formed between the contact protrusions 110e.

The depression portion 110f is concavely formed between the contact protrusions 110e to accommodate particles introduced through the upper surfaces of the contact protrusions 110e.

The contact portion 110a has an inclined surface inclined outward in the width direction on an outer surface thereof. Therefore, the contact portion 110a decreases in width from an upper part toward a lower part thereof in the width direction. When the first connection portion 110 is moved downward due to compressive deformation of the elastic portion 150, the contact portion 110a is brought into contact with the support portion 130 through the inclined surface of the outer surface thereof. As a result, a current path connecting the first connection portion 110 and the support portion 130 is formed.

The flange portion 160 extends from the lower surface of the first connection portion 110 in the length direction (±y direction). Specifically, the flange portion 160 extends from a lower surface of the contact portion 110a in the length direction (±y direction). Therefore, the flange portion 160 is provided between a first support portion 130a and the elastic portion 150, and is located to overlap the upper catch portion SP1 in the width direction (±x direction). When an eccentric pressing force from the connection terminal 410 acts on the electrically conductive contact pin 100c according to the third embodiment, the flange portion 160 is brought into contact with the support portion 130 and supported by the support portion 130.

This prevents the electrically conductive contact pin 100c according to the third embodiment from being excessively buckled and deformed horizontally due to the eccentric pressing force.

The flange portion 160 has a vertical outer surface.

The flange portion 160 has a first end connected to a lower end of the inclined outer surface of the contact portion 110a and a second end serving as a free end.

The flange portion 160 is moved downward due to compressive deformation of the elastic portion 150 and brought into contact with the stopper portion 170.

The electrically conductive contact pin 100c according to the third embodiment includes the stopper portion 170 extending from an inner surface of the support portion 130 inward in the width direction (±x direction) and connected to a side of a curved portion 154. Specifically, the electrically conductive contact pin 100c according to the third embodiment includes a first stopper portion 170a extending inward in the width direction (±x direction) from an inner surface of the first support portion 130a, connected to a side of at least one curved portion 154 of the elastic portion 150, and provided between the first support portion 130a and the curved portion 154.

The flange portion 160 is moved only to a position where it is brought into contact with the first stopper portion 170a and is limited in downward movement position.

Before compressive deformation of the elastic portion 150, a separation distance R having a predetermined length exists between a lower surface of the flange portion 160 and an upper surface of the first stopper portion 170a.

The lower catch portion SP2 is located to correspond to the inclined extension portion IC1 of the support portion 130 in the width direction (±x direction). An inclined portion IC2 of the lower catch portion SP2 has a flat upper surface at a second end thereof serving as a free end. A shoulder portion 134b of the lower catch portion SP2 is provided through the flat upper surface of the second end of the inclined portion IC2. In other words, in the electrically conductive contact pin 100c according to the third embodiment, the shoulder portion 134b is formed by the flat upper surface of the second end of the inclined portion IC2.

When the electrically conductive contact pin 100c according to the third embodiment is inserted into a first side opening of a guide hole GH and then a lower part of the electrically conductive contact pin 100c according to the third embodiment passes through a second side opening of the guide hole GH and the lower catch portion SP2 is restored, the shoulder portion 134b formed as a flat surface is brought into contact with a lower surface of the guide plate GP. The lower catch portion SP2 is supported by the lower surface of the guide plate GP by bringing the shoulder portion 134b into contact with the lower surface of the guide plate GP.

The electrically conductive contact pin 100c according to the third embodiment includes an auxiliary shoulder portion 134d protruding outward in the width direction (±x direction) on at least a part of the support portion 130 in the length direction (ty direction). Specifically, in the electrically conductive contact pin 100c according to the third embodiment, the auxiliary shoulder portion 134d is provided through a portion protruding outward in the width direction (±x direction) from an outer surface of a portion that connects the vertical portion 130e and the inclined extension portion IC1. In addition, the auxiliary shoulder portion 134d is provided by forming the portion connecting the inclined extension IC1 and the vertical portion 130e to have a thickness in the width direction (±x direction) larger than that of the vertical portion 130e. The auxiliary shoulder portion 134d has a flat upper surface.

The auxiliary shoulder portion 134d includes a first auxiliary shoulder portion 5001 provided at a portion connecting a first inclined extension portion 2001 and a first vertical portion 4001, and a second auxiliary shoulder portion 5002 provided at a portion connecting a second inclined extension portion 2002 and a second vertical portion 4002.

When the lower part of the electrically conductive contact pin 100c according to the third embodiment passes through the second side opening of the guide hole GH, the inclined extension portion IC1 is restored outward in the width direction (±x direction) together with the lower catch portion SP2. The auxiliary shoulder portion 134d is provided at the portion connecting the inclined extension portion IC1 and the vertical portion 130e and corresponds to the lower surface of the guide plate GP as the inclined extension portion IC1 is restored.

Then, the electrically conductive contact pin 100c according to the third embodiment is forcibly pushed upward (±y direction). Therefore, the upper surfaces of the shoulder portion 134b and the auxiliary shoulder portion 134d are brought into contact with and supported by the lower surface of the guide plate GP. The electrically conductive contact pin 100c according to the third embodiment is brought into contact with and supported by the lower surface of the guide plate GP through the shoulder portion 134b and the auxiliary shoulder portion 134d, thereby being prevented from being separated in the direction of the first side opening (upward (±y direction)).

The second connection portion 120 includes three pad connection protrusions 120c extending downward from the connection body 120a.

The second connection portion 120 is moved upward (±y direction) due to a pressing force of a pad 310 to bring two pad connection protrusions 120c on outer peripheral sides among the three pad connection protrusions 120c into contact with an inner surface of the inclined extension portion IC1. As a result, a current path connecting the second connection portion 120 and the support portion 130 is formed.

Although the preferred embodiments of the present disclosure have been disclosed for illustrative purposes, those skilled in the art will appreciate that various modifications, additions, and substitutions are possible, without departing from the scope and spirit of the present disclosure as disclosed in the accompanying claims.

### DESCRIPTION OF THE REFERENCE NUMERALS IN THE DRAWINGS

110: first connection portion
120: second connection portion
130: support portion
140: connecting portion
150: elastic portion
160: flange portion
170: stopper portion
200: installation member
400: test object
410: connection terminal
SP1: upper catch portion
SP2: lower catch portion

1. An electrically conductive contact pin having a lower catch portion,
wherein the lower catch portion is compressed and deformed inward in a width direction, inserted into a first side opening of a guide hole of a guide plate, and restored while passing through a second side opening of the guide hole and brought into contact with a lower surface of the guide plate so that the electrically conductive contact pin is prevented from being separated in a direction of the first side opening.

2. The electrically conductive contact pin of claim 1, wherein the electrically conductive contact pin comprises:
a first connection portion;
a second connection portion;
a support portion extending in a length direction; and
an elastic portion connected to at least one of the first connection portion and the second connection portion and elastically deformable along the length direction,
wherein the lower catch portion is connected to the support portion.

3. The electrically conductive contact pin of claim 1, wherein the electrically conductive contact pin comprises:
a first connection portion;
a second connection portion;
a support portion extending in a length direction; and
an elastic portion connected to at least one of the first connection portion and the second connection portion and elastically deformable along the length direction,
wherein the lower catch portion is connected to the second connection portion.

4. The electrically conductive contact pin of claim 1, wherein the lower catch portion comprises an inclined portion inclined inward in the width direction.

5. The electrically conductive contact pin of claim 4, wherein the lower catch portion further comprises a shoulder portion extending linearly from an end of the inclined portion,
wherein when the lower catch portion is restored while passing through the second side opening of the guide hole, an upper surface of the shoulder portion is brought into contact with the lower surface of the guide plate to prevent the electrically conductive contact pin from being separated in the direction of the first side opening.

6. The electrically conductive contact pin of claim 4, wherein the lower catch portion further comprises a shoulder portion protruding inward in the width direction from an end of the inclined portion,
wherein when the lower catch portion is restored while passing through the second side opening of the guide hole, an upper surface of the shoulder portion is brought into contact with the lower surface of the guide plate to prevent the electrically conductive contact pin from being separated in the direction of the first side opening.

7. The electrically conductive contact pin of claim 6, wherein the upper surface of the shoulder portion is formed as a flat surface.

8. The electrically conductive contact pin of claim 2, wherein the electrically conductive contact pin further comprises: an auxiliary shoulder portion protruding outward in the width direction on at least a part of the support portion in the length direction,
wherein when the lower catch portion is restored while passing through the second side opening of the guide hole, an upper surface of the auxiliary shoulder portion is brought into contact with the lower surface of the guide plate to prevent the electrically conductive contact pin from being separated in the direction of the first side opening.

9. The electrically conductive contact pin of any one of claims 2 and 3, wherein the electrically conductive contact pin further comprises: an upper catch portion corresponding vertically to the lower catch portion in the length direction,
wherein the upper catch portion is connected to the support portion and is formed to protrude outward from the support portion in the width direction.

10. The electrically conductive contact pin of claim 2, wherein the first connection portion comprises:
a contact portion; and
an upward protrusion.

11. The electrically conductive contact pin of claim 2, wherein the first connection portion comprises:
a contact portion;
a contact cavity formed in the contact portion; and
a contact protrusion extending in the length direction from an upper surface of the contact portion.

12. The electrically conductive contact pin of claim 2, wherein the second connection portion comprises:
a connection body;
a connection cavity formed in the connection body; and
at least one pad connection protrusion provided on a lower surface of the connection body.

13. The electrically conductive contact pin of claim 2, wherein the electrically conductive contact pin further comprises:
a flange portion connected to at least one of the first connection portion and the elastic portion and provided between the support portion and the elastic portion.

14. The electrically conductive contact pin of claim 13, wherein the flange portion extends in the length direction from a lower surface of the first connection portion and is provided between the support portion and the elastic portion.

15. The electrically conductive contact pin of claim 2, wherein the electrically conductive contact pin further comprises:
a stopper portion connected to at least one of the support portion and the elastic portion and extending in the width direction.

16. The electrically conductive contact pin of claim 3, wherein the electrically conductive contact pin further comprises:
a stopper portion formed by a portion recessed inward in the width direction on at least a part of the support portion.

17. The electrically conductive contact pin of claim 1, wherein the electrically conductive contact pin is formed by stacking a plurality of metal layers in a thickness direction of the electrically conductive contact pin.

18. The electrically conductive contact pin of claim 1, wherein the electrically conductive contact pin comprises:
a plurality of fine trenches provided on a side surface thereof.
